(19) United States
(12) Patent Application Publication
(10) Pub. No.: US 2010/0227158 A1
(43) Pub. Date: Sep. 9, 2010

(54) SURFACE MODIFIED ELECTRICAL INSULATION SYSTEM WITH IMPROVED TRACKING AND EROSION RESISTANCE

(75) Inventors: Stephen CLIFFORD, Bremgarten (CH); Bandeep Singh, Wytheville, VA (US); Andrej Krivda, Wettingen (CH); Lars E. Schmidt, Zurich (CH); Felix Greuter, Baden-Ruetihof (CH); Veronika Schmid, Baden (CH)

Correspondence Address: BUCHANAN, INGERSOLL & ROONEY PC, POST OFFICE BOX 1404, ALEXANDRIA, VA, 22313-1404, US

(73) Assignee: ABB Research Ltd., Zurich (CH)

(21) Appl. No.: 12/755,703

(22) Filed: Apr. 7, 2010

Related U.S. Application Data
(63) Continuation of application No. PCT/EP2007/060634, filed on Oct. 8, 2007.

(51) Int. Cl. B32B 27/00; B32B 27/38; B32B 27/40; C23C 16/44

(52) U.S. Cl. 428/335; 428/332; 427/569

(57) ABSTRACT

Surface modified electrical insulation system including a hardened or cured synthetic polymer composition including at least one filler, wherein the surface of said synthetic polymer composition is modified by being coated with a thin coating. The thin coating is applied by a plasma enhanced chemical vapor deposition (PECVD) with a thickness within the range of about 50 nanometer to about 50 μm; and/or a by a sol-gel technique with a thickness within the range of about 0.5 micron to about 1 mm. The thin coat is an electrically non-conductive polymeric material having a melting point which is distinctly higher than the melting point or degradation temperature of the synthetic filler containing polymer composition.

### RELATED APPLICATION

This application claims priority as a continuation application under 35 U.S.C. §120 to PCT/EP2007/060634, which was filed as an International Application on Oct. 8, 2007 designating the U.S., the entire content of which is hereby incorporated by reference in its entirety.

### FIELD

The present disclosure relates to a surface modified electrical insulation system with improved tracking and erosion resistance. The present disclosure also relates to a surface modified electrical insulation system including a synthetic polymer composition having a filler and further additives. The synthetic polymer composition can be coated with a thin coating composition that has a melting point which can be distinctly higher than the melting point or degradation temperature of the polymer composition.

### BACKGROUND INFORMATION

Outdoor electrical insulations often are exposed to surface discharges in-service. The temperature of surface discharges can be generally higher than 1000° C. (>1000° C.). In the case of electrical insulation systems based on synthetic polymers filled with a filler composition, these high discharge temperatures can lead to erosion and carbonization (also called tracking) of the insulation material because the degradation temperature of polymeric insulation material typically can be much lower than 1000° C., and generally lower than 400° C. (<400° C.). Epoxy resin compositions generally can start to degrade at temperatures around 250° C.

In U.S. Pat. No. 6,541,118 an electrical insulator with a molding made of ceramic and a hydrophobic coating applied to the surface of the molding is disclosed. The hydrophobic coating includes a plasma polymer having been applied directly to the ceramic. Ceramic materials can be very stable having a high dimensional stability and a great resistance to heat. It therefore can be possible to coat the ceramic surfaces with a thin coating, for example a plasma polymer coating, applied directly to the ceramic surface.

Outdoor electrical insulations, especially for high-voltage applications, can be based on synthetic polymers filled with a filler composition. Such preferred synthetic polymer compositions can be, for example, epoxy resin compositions including fillers and further additives. These epoxy resin compositions can often be based on cycloaliphatic epoxy resins, having a silica filler content within the range of about 60% to 80%, and generally about 65%, by weight, calculated to the total weight of the insulation system. There is a need to increase the time during which such polymeric insulation can withstand exposure to the high temperatures of surface discharges without degradation. The resistance of such insulators to the high temperatures of surface discharges, without degradation can be measured with the (International Electrotechnical Commission) IEC 60587 inclined plane tracking standard test.

### SUMMARY

An exemplary surface modified electrical insulation system includes a hardened or cured synthetic polymer composition including at least one filler. The surface of the synthetic polymer composition can be modified by being coated with a thin coating. The thin coating can be applied by plasma enhanced chemical vapor deposition (PECVD) with a thickness within the range of about 50 nanometer to about 50 μm and/or a sol-gel technique with a thickness within the range of about 0.5 micron to about 1 mm. The thin coat can be an electrically non-conductive polymeric material having a melting point which is higher than the melting point or degradation temperature of the synthetic filler containing polymer composition.

An exemplary method of producing a surface modified electrical insulation system, includes providing a hardened or cured synthetic polymer composition including at least one filler. The surface of the synthetic polymer composition can be applied with a thin coating with a thickness within the range of about 50 nanometer to about 50 μm by a plasma enhanced chemical vapor deposition (PECVD) and/or by a sol-gel technique with a thickness within the range of about 0.5 micron to about 2 mm. An electrically non-conductive monomeric material can be used for the thin coating.

### DETAILED DESCRIPTION

An exemplary electrical insulation system made from a synthetic polymer composition, especially made from a cycloaliphatic epoxy resin composition including at least one filler and optionally further additives, can be coated with a thin coat of a thickness within the range of about 50 nanometer (50 nm or 50×10⁻³ μm) to about 50 μm (micron). The thin coat can be electrically non-conductive polymeric material and can have a melting point which is distinctly higher than the melting point of the synthetic filler containing polymer composition. This can increase markedly the time during which such polymeric insulation system can withstand exposure to the high temperatures of surface discharges without degradation. Preferably the polymeric insulation system can have a filler content within the range of about 60% to 80% by weight calculated to the total weight of the insulation system. This effect is surprising because the surface of an electrical insulation system made from a synthetic polymer composition is permeable for components within the insulation system and numerous other properties such as the dimensional stability and resistance to heat are very much different from ceramic surfaces.

The present disclosure specifically refers a exemplary surface modified electrical insulation system including a hardened or cured synthetic polymer composition including at least one filler and optionally further additives. The surface of the synthetic polymer composition can be modified by being coated with a thin coating.
the thin coating can be applied by a plasma enhanced chemical vapor deposition (PECVD) with a thickness within the range of about 50 nanometer to about 50 μm; and/or
the thin coating can be applied by a by a sol-gel technique with a thickness within the range of about 0.5 micron to about 1 mm; and
the thin coat can be an electrically non-conductive polymeric material having a melting point which can be distinctly higher than the melting point or degradation temperature of the synthetic filler containing polymer composition.

According to the present disclosure it can also be possible that both types of thin coatings are applied, either one on top of the other in any desired sequence.

The present disclosure further refers to an exemplary method of producing the surface modified electrical insulation system. The present disclosure further refers to the use of the exemplary surface modified electrical insulation system as an insulation system in electrical articles. The present disclosure further refers to exemplary electrical articles including the surface modified electrical insulation system.

The exemplary surface modified electrical insulation system according to the present disclosure can include a synthetic polymer composition. The polymer may be selected from known polymers used in electrical insulator composition, such as polyesters, for example poly(methyl-methacrylate), or poly(alkylacrylonitrile), or duroplastic polymers such as polyurethanes or epoxy resin compositions or any other suitable polymer. Preferred are epoxy resin compositions, preferably cycloaliphatic epoxy resin compound. The epoxy resin compositions generally contain a hardener, a curing agent to accelerate the curing process, as well as further additives. These compounds are known per se.

Cycloaliphatic epoxy resin compounds as used within the scope of the present disclosure can contain at least two 1,2-epoxy groups per molecule.

Cycloaliphatic epoxy resin compounds useful for the present disclosure include unsubstituted glycidyl groups and/or glycidyl groups substituted with methyl groups. These glycidyl compounds have an epoxy value (equiv./kg) preferably of at least three, preferably at least four and especially at about five or higher, preferably about 5.0 to 6.1. Preferred are for example optionally substituted epoxy resins of formula (I):

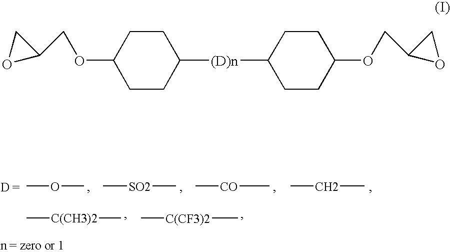

Compounds of formula (I) wherein D is —(CH₂)— or [—C(CH₃)₂—] are preferred. Further cycloaliphatic epoxy resins to be used within the scope of the present disclosure further are for example hexahydro-o-phthalic acid-bis-glycidyl ester, hexahydro-m-phthalic acid-bis-glycidyl ester or hexahydro-p-phthalic acid-bis-glycidyl ester. Preferred cycloaliphatic epoxy resin compounds can be liquid at room temperature or when heated to a temperature of up to about 65° C. Preferred cycloaliphatic epoxy resin compounds are for example Araldite® CY 184 (Huntsman Advanced Materials Ltd.), a cycloaliphatic epoxy resin compound (diglycidylester) having an epoxy content of 5.80-6.10 (equiv/kg) or Araldite® CY 5622 (Huntsman Advanced Materials Ltd.), a modified epoxy resin compound (diglycidylester) having an epoxy content of 5.80-6.10 (equiv/kg). Araldite® CY 5622 is a hydrophobic cycloaliphatic epoxy formulation for hydrophobicity transfer and recovery in outdoor epoxy resin compositions. A hydrophobic cycloaliphatic epoxy formulation means that the filler material has been pre-treated with a silane or a silane additive has been added to the composition.

The epoxy resin composition to be cured includes generally the epoxy resin, the hardener and the curing agent. Hardeners are for example hydroxyl and/or carboxyl containing polymers such as carboxyl terminated polyester and/or carboxyl containing acrylate- and/or methacrylate polymers and/or carboxylic acid anhydrides. Useful hardeners are further aliphatic, cycloaliphatic polycarbonic acids. Preferred anhydrides are liquid cycloaliphatic anhydrides with a viscosity at 25° C. of about 70-80 mPa s. Such a liquid cycloaliphatic anhydride hardener is for example Aradur® HY 1235 (Huntsman Advanced Materials Ltd.). The optional hardener can be used in concentrations within the range of 0.2 to 1.2, equivalents of hardening groups present, e.g. one anhydride group per 1 epoxide equivalent.

The inorganic filler can be present in the synthetic polymer composition within the range of about 60% by weight to about 80% by weight, preferably within the range of about 60% by weight to about 70% by weight, and preferably at about 65% by weight, calculated to the total weight of the synthetic polymer composition.

The inorganic filler can have an average grain size as known for use in electrical insulation systems and is generally within the range of 10 micron up to 3 mm and is not critical for the present disclosure. The mineral filler can be selected from conventional filler materials as are generally used as fillers in electrical insulations. Preferably the filler is selected from silica, quartz, known silicates, aluminium oxide, aluminium trihydrate [ATH], titanium oxide or dolomite [CaMg(CO₃)₂], metal nitrides, such as silicon nitride, boron nitride and aluminium nitride or metal carbides, such as silicon carbide. Preferred are silica and quartz with a minimum SiO₂-content of about 95-97% by weight.

As optional additives the composition may include further a curing agent (accelerant) for enhancing the polymerization of the epoxy resin with the hardener. Further additives may be selected from wetting/dispersing agents, flexibilizers, plasticizers, antioxidants, light absorbers, silicones, pigments, flame retardants, fibers and other additives generally used in electrical applications. These are known to the expert and not critical for the present disclosure.

If the thin coating is applied by a plasma enhanced chemical vapor deposition (PECVD) its thickness can be within the range of about 50 nm to about 50 μm; preferably within the range of about 100 nm to about 30 μm, preferably within the range of about 200 nm to about 20 μm, preferably within the range of about 250 nm to about 10 μm, preferably within the range of about 300 nm to about 5 μm.

The thin coat can be an electrically non-conductive polymeric material and includes a plasma polymer or an amorphous glass-like coating. The thin coat has a melting point which can be distinctly higher than the melting point of the synthetic polymer composition, i.e. the melting point is at least 200° C. higher than the melting point or degradation temperature of the synthetic polymer composition.

A polymer coating applied by a plasma enhanced chemical vapor deposition (PECVD) are also named “plasma polymer.” Plasma polymers made by PECVD are different from synthetic polymers made by polymerization of a monomeric starting material. When using plasma enhanced chemical vapor deposition (PECVD), the monomeric starting material can be heated in a carrier gas to a relatively high temperature, optionally together with a filler component. The plasma yields ionized molecules by working at high temperatures initiated by applying e.g. a strong electrical field or radio frequency (RF). The plasma polymer can be formed on the surface of the synthetic polymer composition by directing the material stream ionized in the plasma reactor onto the surface of the synthetic polymer composition to be coated. Analogous procedures by using plasma technology have been described and are known to the expert.

As a carrier gas, preferably oxygen, nitrogen, or a hydrocarbon for example, preferably methane or ethane can be used. As starting materials for producing the thin coat preferably volatile compounds having non-polar groups are used, preferably selected from organosilane compounds, alkoxyorthosilicates, organofluorine compounds, and mixtures thereof. Preferred are compounds selected from hexaalkyldisiloxanes, preferably hexamethyldisiloxane or vinyltrimethylsilane; tetraalkylorthosilicates, preferably tetraethylorthosilicate; or a mixture of these compounds. These compounds may optionally be mixed with a fine filler material, preferably with fine silica or fine quartz, having a minimum SiO₂-content of about 95-97% by weight, and having preferably an average grain size within the nano size range or very low micron size range (1 μm to 10 μm).

A plasma polymer can be composed of numerous different units originating from the ionized plasma particles and does not have a precise chemical composition as compared to a synthetic polymer polymerized by known polymerization techniques. Unexpectedly a surprisingly stable hydrophobic glass-like plasma polymer can be obtained on the surface of the synthetic polymer composition, modifying the surface, and wherein the glass-like material also has a high melting point and/or degradation temperature.

The thin coating can be applied by a sol-gel technique with a thickness within the range of about 0.5 μm to about 2 mm; preferably within the range of about 1.0 μm to about 1 mm, preferably within the range of about 1 μm to about 500 μm, preferably within the range of about 1 μm to about 100 μm.

Coatings made from silane based sol-gel (a densely cross-linked network, obtained after removal of solvent) on synthetic polymer compositions, preferably on cycloaliphatic epoxy compositions, surprisingly can improve tracking and erosion resistance of the exemplary insulation system made according to the present disclosure.

Silanes to be employed within the silane based sol-gel to form a thin layer on synthetic polymer compositions according to the present disclosure preferably are selected from alkoxysilanes and florosilanes. Organo-alkoxysilanes refer to the class of alkoxysilane molecules, having one organic chain and three alkoxy groups linked to the silicon atom. It corresponds to the following formula: [R—Si(OR₁)₃], wherein R is a further (—OR₁)-substituent, or alkyl or a substituted alkyl, preferably (C₁-C₂₂)-alkyl, optionally substituted with an amine, an epoxy, an acrylate, a methacrylate, a phenolic residue or a melamine-residue. R₁ preferably is (C₁₋₄-alkyl, preferably methyl. Thus, upon hydrolysis and condensation a combination of organic-inorganic network can be obtained. The reaction sequence and the special treatment to obtain a thin film resp. coat is known and described in E. P. Plueddmann, Silane Coupling Agents, 2. Ed., 1990, Plenum Press, New York.

Suitable compounds to be used to carry out the present disclosure which correspond to the formula [R—Si(OR₁)₃] as defined above, are for example hexadecyltrimethoxysilane, 3-glycidoxypropyltrimethoxysilane, 3-glycidoxypropyltriethoxysilane, 3-aminopropyltriethoxysilane, tetraethoxysilane, methacryloxypropyltrimethoxysilane, vinyltrialkoxysilane, where the alkoxy can be an ethoxy or methoxy group.

The reactions of hydrolysis and condensation can be strongly dependent on the acid value (pH-value), but under optimum conditions hydrolysis can be comparatively quick (some minutes) while the condensation reaction can be slower (some hours). Under mildly acidic conditions, neutral alkoxysilanes hydrolyze to form monomeric silanetriols which then condense slowly to polymeric organic siloxanols. During the initial stages of reaction there can be a competition between the reactions of hydrolysis and condensation. During hydrolysis, one has to take extra care to avoid cross-linking, as, if it happens, then the mixture will react to a high molecular weight polymerized siloxane and can be unable to form a coat on the desired surface. Therefore, one has to prepare any silane based sol-gel in two steps. In the first step, hydrolysis of silane solution in a solvent is carried out. Once hydrolyzed, in a subsequent step, this mixture is coated on the substrate, preferably an epoxy substrate, and cross-linked.

The present disclosure also refers to an exemplary method of producing the surface modified electrical insulation system including a synthetic polymer composition including at least one filler and optionally further additives, as defined in the present disclosure, including the following: (i) providing a hardened or cured synthetic polymer composition including at least one filler and optionally further additives, using known methods; and (ii) applying to the surface of the synthetic polymer composition a thin coating with a thickness within the range of about 50 nanometer to about 50 μm (as defined herein above) the thin coating can be applied by a plasma enhanced chemical vapor deposition (PECVD); and/or applying to the surface of the synthetic polymer composition a thin coating being with a thickness within the range of about 0.5 micron to about 2 mm (as defined herein above) by a sol-gel technique and (iii) wherein for producing the thin coating, an electrically non-conductive monomeric material as defined herein above is used.

Preferred uses of the exemplary surface modified electrical insulation system can be in power transmission and distribution applications, such as electrical insulations, especially in the field of impregnating electrical coils and in the production of electrical components such as transformers, embedded poles, bushings, high-voltage insulators for indoor and outdoor use, especially for outdoor insulators associated with high-voltage lines, as long-rod, composite and cap-type insulators, sensors, converters and cable end seals as well as for base insulators in the medium-voltage sector, in the production of insulators associated with outdoor power switches, measuring transducers, lead-throughs, and over-voltage protectors, in switchgear construction.

The following examples illustrate the disclosure.

### Example 1

Example 1 describes the manufacturing of a glass-like coating with a thickness in the range of 0.3 to 1.2 μm, deposited by plasma enhanced chemical vapor deposition (PECVD) on a substrate of a cycloaliphatic outdoor epoxy insulation. PECVD can be carried out so that the substrate is exposed to not higher than about 100° C.

An oxygen plasma, in an atmosphere of hexamethylendisiloxane (HMDSO) is used. Thereby, the bonds of the HMDSO molecules are broken by the high energy of the plasma and accelerated towards the substrate. When the elements recombine on the substrate surface, a number of chemical reactions take place and oxygen, hydrogen and carbon dioxide are formed and evolve. The coating which forms on the substrate surface can be of a dense cross-linked amorphous structure and substantially contains silicon atoms and oxygen atoms in a ratio of about 1:2. It is difficult to determine the precise composition of the coating. The coating therefore is named “plasma polymer” or “SiOₓ-polymer.”

### Substrate Manufacture

The cycloaliphatic epoxy (CEP) formulation used as the substrate material in this example is given in Table 1. All components, except the catalyst, were pre-heated to 45° C. These were then intensively mixed together at ambient pressure with a propeller mixer. The complete mixture was then degassed in a vacuum oven, with mixing, at about 5 mbar, for 20 minutes at 60° C.

The mixture was then molded into 6 mm thick plates using steel moulds pre-heated to 90° C. and coated with Huntsman QZ13 mould-release agent. A curing cycle of 2 hours at 90° C., followed by 24 hours at 140° C., was applied to ensure complete curing.

TABLE 1

| Components | phr |
|---|---|
| Huntsman CY184 (Resin) | 100 |
| Huntsman HY1235 (Hardener) | 90 |
| Huntsman DY062 (Catalyst) | 0.54 |
| Huntsman DW9134 (Pigment, TiO₂) | 2.7 |
| Quarzwerke W 12EST (Filler) | 359 |

Araldite® CY 184: Cycloaliphatic epoxy resin (Huntsman)
Aradur®HY1235: modified cycloaliphatic anhydride (Huntsman)
Accelerator DY062: liquid tertiary amine

### W12 EST: SiO₂ (Quarzwerke GmbH)

### PECVD Coating

The SiOₓ coatings were applied to the CEP substrates by plasma enhanced chemical vapor deposition (PECVD). The PECVD equipment used was essentially a vacuum chamber containing a radio frequency (RF) plasma source. The equipment was designed for the coating of flat polymeric film substrates. The dimensions of the tracking erosion test samples were 6 mm×50 mm×120 mm. The SiOₓ coating applied had a thickness of 0.3 μm. During the deposition process, the temperature of the epoxy did not exceed 100° C.

Further samples were coated with multiples of 0.3 μm thickness, i.e. 0.6 μm, 0.9 μm and 1.2 μm. The desired coating thickness was achieved by varying the deposition time of the coating. For achieving a thickness of 0.3 μm a deposition time of 60 seconds was used and extended to 120 seconds, 280 seconds and 240 seconds respectively to achieve the greater thickness.

To ensure good adhesion of the SiOₓ coating to the CEP substrate, the surface of the sample was cleaned in an ultrasonic bath, under acetone, before placing in the chamber. In the chamber, the plasma was ignited in the absence of the working gas to energize the sample surface. The parameters for this pretreatment and the subsequent deposition of the coating are given in Table 2.

TABLE 2
Chamber evacuation

| | |
|---|---|
| Base pressure | 3 − 8 × 10⁻³ mbar |

Plasma pre-treatment

| | | |
|---|---|---|
| Power (RF) | 50 | W |
| Volume of oxygen (O₂) | 50 | sccm |
| Pressure | 0.1 | mbar |
| Time | 6 | s |

Deposition

| Power (RF) | 212 | W |
|---|---|---|
| Volume of HMDSO | 10 | sccm |
| Volume of O₂ | 150 | sccm |
| O₂:HMDSO (mix ratio) | 15:1 | |
| Pressure | 0.1 | mbar |
| Temperature of CEP substrate | 25° | C. |
| Time of deposition | 60 | s |

### Tracking and Erosion Resistance (IEC 60587)

The inclined-plane tracking and erosion test (IEC 60587 ed. May 2007) was used to evaluate the tracking resistance and erosion resistance of the coated and uncoated samples. Four test voltage levels (2.5 kVᵣₘₛ, 3.5 kVᵣₘₛ, 4.5 kVᵣₘₛ and 6 kVᵣₘₛ) are specified by the standard, which are the potentials applied between the two electrodes at the bottom and top of the sample during testing. A sodium chloride salt solution, containing a non-ionic wetting agent, and with a defined conductivity, flows over the sample surface from the top to the bottom electrode with a defined flow rate. This arrangement causes arcing on the surface of the sample, concentrated at the bottom electrode. The standard allows two methods of determining a sample failure, referred to as criteria A and B. In this work criteria A was used, defined as the leakage current across a sample exceeding 60 mAᵣₘₛ for a duration of 2 seconds. A sample is determined to have passed if it survives 6 hours of testing without failure. For a material to pass the test, all 5 samples should survive for 6 hours.

The tracking and erosion resistance of coated and uncoated CEP samples was evaluated by the inclined plane method. The CEP samples were tested with and without abrading. Results are given in Table 3.

TABLE 3
(Inclined plane tracking and erosion
test results according to IEC 60587)

| | 3.5 kVᵣₘₛ | 4.5 kVᵣₘₛ | 6 kVᵣₘₛ |
|---|---|---|---|
| CEP (abraded) | Passed | Failed | |
| | | (all 5 samples failed | |
| | | within 30 minutes) | |
| CEP (not abraded) | | Failed | |
| | | (4 samples passed, | |
| | | 1 sample | |
| | | failed after 40 minutes) | |
| CEP with 0.3 μm SiO₂ | | Passed | Passed |
| coating (not abraded) | | | |

Where a material is classified as “failed” for a particular test voltage, 1 or more of the 5 samples had failed the test. Where it is classified as passed, none of the 5 samples failed.

The samples with coating thickness of 0.6 μm, 0.9 μm and 1.2 μm were tested together at 6 kVᵣₘₛ. All samples survived 6 hours and no difference was observed between their performance and those of the 0.3 μm thick coatings. The results demonstrate that tracking and erosion measurements show a distinct improvement in tracking and erosion resistance of the PECVD coated samples, according the IEC inclined plane test.

### Example 2

Example 2 describes the manufacturing of a glass-like coating with a thickness in the range of 0.5 μm to 2 mm, deposited by the hybrid sol-gel coating method on a substrate of a cycloaliphatic outdoor epoxy insulation. The substrate manufacture was carried out as described in Example 1, with the components as given in Table 1.

Silanes used in the hybrid sol-gel coating method were functionalized-alkoxysilanes, i.e. tetraethoxysilane (TEOS), 3-g lycidyloxypropyltrimethoxysilane (GPTMS, an epoxized trimethoxysilane) and hexadecyltrimethoxysilane (HDMS) having a long hydrophobic chain substituent.

Coating formulations and process conditions for silane based sol-gel coatings are shown in Table 4. These chemicals were mixed together at room temperature and kept separately to avoid any crosslinking between them. Coatings were carried out at room temperature.

TABLE 4

| | Molar Ratios | | | | | | | |
|---|---|---|---|---|---|---|---|---|
| Coating | | | | | | | | Process |
| Formulation | TEOS | GPTMS | HDMS | Water | Ethanol | Aerosil | HCl | conditions |
| A | 2 | 1 | -.- | 2 | 27 | -.- | 0.07 | (A) |
| B | 1 | -.- | -.- | 2 | 27 | -.- | 0.07 | (B) |
| C | -.- | 1 | -.- | 2 | 27 | -.- | 0.07 | (C) |
| D | -.- | -.- | 1 | 2 | 27 | -.- | 0.07 | (D) |
| E | -.- | -.- | 1 | -.- | 27 | 5% | 0.07 | (E) |
| | | | | | | b.w. of | | |
| | | | | | | HDMS | | |

### Process Conditions:

(A) First hydrolyse TEOS for 6 hours and then slowly add GPTMS and stir for 18 hours at 25° C.
(B) Hydrolysis for 10 hours at 25° C.
(C) Hydrolysis for 10 hours at 25° C.
(D) White precipitates were obtained after 1 minute of hydrolysis, therefore this coating formulation was not used
(E) Mixed for 4 hours at 25° C.

### Tracking and Erosion Resistance (IEC 60587)

For the sol-gel coatings of formulation A or B+C (in the ratio of 70:30 vol. %) or B+C+E (in the ratio of 60:30:10 vol. %) on CEP substrates and curing for 2 hrs. at 100° C., according to this Example 2, tracking and erosion resistance of CEP samples was found to be improved according to IEC 60587. Results obtained were analogous to Example 1, Table 3.

Thus, it will be appreciated by those skilled in the art that the present invention can be embodied in other specific forms without departing from the spirit or essential characteristics thereof. The presently disclosed embodiments are therefore considered in all respects to be illustrative and not restricted. The scope of the invention is indicated by the appended claims rather than the foregoing description and all changes that come within the meaning and range and equivalence thereof are intended to be embraced therein.

What is claimed is:

1. Surface modified electrical insulation system, comprising
a hardened or cured synthetic polymer composition including at least one filler, wherein the surface of said synthetic polymer composition is modified by being coated with a thin coating;
said thin coating being applied by at least one of a plasma enhanced chemical vapor deposition (PECVD) with a thickness within the range of about 50 nanometer to about 50 μm and a sol-gel technique with a thickness within the range of about 0.5 micron to about 1 mm; and wherein
said thin coat being an electrically non-conductive polymeric material having a melting point which is higher than the melting point or degradation temperature of the synthetic filler containing polymer composition.

2. Surface modified electrical insulation system according to claim 1, wherein said thin coating being applied by the plasma enhanced chemical vapor deposition (PECVD) and the sol-gel technique each being applied either one on top of the other in any desired sequence.

3. Surface modified electrical insulation system according to claim 1, wherein said synthetic polymer is selected from polyesters, preferably poly(methylmethacrylate), or poly(alkylacrylonitrile).

4. Surface modified electrical insulation system according to claim 1, wherein said synthetic polymer is an epoxy resin composition, preferably based on a cycloaliphatic epoxy resin compound.

5. Surface modified electrical insulation system according to claim 1, wherein an inorganic filler is present in the synthetic polymer composition within the range of about 60% by weight to about 80% by weight of the total weight of the synthetic polymer composition.

6. Surface modified electrical insulation system according to the claim 1, wherein the synthetic polymer composition comprises additives selected from at least one of wetting/dispersing agents, flexibilizers, plasticizers, antioxidants, light absorbers, silicones, pigments, flame retardants, fibers and other additives generally used in electrical applications.

7. Surface modified electrical insulation system according to claim 1, wherein said thin coating is applied by a plasma enhanced chemical vapor deposition (PECVD) with a thickness within the range of about 50 nm to about 50 μm.

8. Surface modified electrical insulation system according to claim 7, wherein the starting materials for producing the thin coat is a volatile compound having non-polar groups, and is preferably selected from at least one of organosilane compounds, alkoxyorthosilicates, organofluorine compounds, and mixtures thereof.

9. Surface modified electrical insulation system according to claim 8, wherein said starting material is selected from at least one of hexaalkyldisiloxanes, hexamethyldisiloxane or vinyltrimethylsilane; tetraalkylorthosilicates, tetraethylorthosilicate; or a mixture of these compounds.

10. Surface modified electrical insulation system according to claim 9, wherein said starting materials are mixed with a fine filler material, preferably with fine silica or fine quartz, having a minimum SiO₂-content of about 95-97% by weight, and having preferably an average grain size within the nano size range or very low micron size range (1 μm to 10 μm).

11. Surface modified electrical insulation system according to claim 1, wherein said thin coating is applied by a sol-gel technique with a thickness within the range of about 0.5 μm to about 2 mm.

12. Surface modified electrical insulation system according to claim 11, wherein said coating is made from silane based sol-gel wherein the starting silanes are selected from alkoxysilanes and florosilanes.

13. Surface modified electrical insulation system according to claim 12, wherein the alkoxysilanes and florosilanes are selected from compounds of formula: [R—Si(OR₁)₃], wherein R is a further (—OR₁)-substituent, or alkyl or a substituted alkyl, preferably (C₁-C₂₂)-alkyl, optionally substituted with an amine, an epoxy, an acrylate, a methacrylate, a phenolic residue or a melamine-residue, and R₁ is (C₁₋₄)-alkyl, preferably methyl.

14. Surface modified electrical insulation system according to claim 13, wherein the alkoxysilanes and florosilanes are selected from the group comprising hexadecyltrimethoxysilane, 3-glycidoxypropyltrimethoxysilane, 3-glycidoxypropyltriethoxysilane, 3-aminopropyltriethoxysilane, tetraethoxysilane, methacryloxypropyltrimethoxysilane, vinyltrialkoxysilane, where the alkoxy can be an ethoxy or methoxy group.

15. Method of producing a surface modified electrical insulation system, comprising:
providing a hardened or cured synthetic polymer composition including at least one filler; and
applying to the surface of said synthetic polymer composition at least one of a thin coating with a thickness within the range of about 50 nanometer to about 50 μm by a plasma enhanced chemical vapor deposition (PECVD) and applying to the surface of said synthetic polymer composition a thin coating with a thickness within the range of about 0.5 micron to about 2 mm by a sol-gel technique and wherein for producing said thin coating an electrically non-conductive monomeric material is used.

16. Method according to claim 15, wherein said thin coating being applied by the plasma enhanced chemical vapor deposition (PECVD) and the sol-gel technique, each being applied, either one on top of the other in any desired sequence.

17. Electrical apparatus comprising a surface modified electrical insulation system according to claim 1.

18. Surface modified electrical insulation system according to claim 1, wherein said synthetic polymer is selected from duroplastic polymers preferably polyurethanes or epoxy resin compositions.

19. Surface modified electrical insulation system according to claim 1, wherein an inorganic filler is present in the synthetic polymer composition within the range of about 60% by weight to about 70% by weight of the total weight of the synthetic polymer composition.

20. Surface modified electrical insulation system according to claim 1, wherein an inorganic filler is present in the synthetic polymer composition within the range of about at about 65% by weight, calculated to the total weight of the synthetic polymer composition.

21. Surface modified electrical insulation system according to claim 1, wherein said thin coating is applied by a plasma enhanced chemical vapor deposition (PECVD) with a thickness within the range of about 100 nm to about 30 μm.

22. Surface modified electrical insulation system according to claim 1, wherein said thin coating is applied by a plasma enhanced chemical vapor deposition (PECVD) with a thickness within the range of about 200 nm to about 20 μm.

23. Surface modified electrical insulation system according to claim 1, wherein said thin coating is applied by a plasma enhanced chemical vapor deposition (PECVD) with a thickness within the range of about 250 nm to about 10 μm.

24. Surface modified electrical insulation system according to claim 1, wherein said thin coating is applied by a plasma enhanced chemical vapor deposition (PECVD) with a thickness within the range of about 300 nm to about 5 μm.

25. Surface modified electrical insulation system according to claim 1, wherein said thin coating is applied by a sol-gel technique with a thickness within the range of about 1.0 μm to about 1 mm.

26. Surface modified electrical insulation system according to claim 1, wherein said thin coating is applied by a sol-gel technique with a thickness within the range of about 1.0 μm to about 500 μm.

27. Surface modified electrical insulation system according to claim 1, wherein said thin coating is applied by a sol-gel technique with a thickness preferably within the range of about 1 μm to about 100 μm.

28. Surface modified electrical insulation system according to claim 1, wherein said electricity non-conductive polymeric material has a melting point that is distinctly higher than the melting point or degradation temperature of the synthetic filler containing polymer composition.
